(19) United States
(12) Patent Application Publication
(10) Pub. No.: US 2009/0011678 A1
(43) Pub. Date: Jan. 8, 2009

(54) METHOD FOR PRODUCING DISPLAY DEVICE AND DISPLAY DEVICE

(75) Inventors: Shinichiro Morikawa, Aichi (JP); Atsushi Minamikawa, Aichi (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/138,980

(22) Filed: Jun. 13, 2008

(30) Foreign Application Priority Data
Jul. 3, 2007 (JP) 2007-174688

(51) Int. Cl. H01J 9/20

(52) U.S. Cl. 445/25

(57) ABSTRACT

Disclosed herein is a method for producing a display device and a display device produced thereby. The method includes the steps of: forming on an element substrate terminal areas for electrical connection of display elements with external circuits; covering the terminal areas with a protective member; sealing the element substrate with a sealing substrate placed thereon, with an adhesive layer interposed between them in such a way as to cover the display elements on the element substrate and also cover the protective member; and removing part of the laminate body composed of the element substrate, the adhesive layer, and the sealing substrate and also removing the protective member, thereby exposing the terminal areas. The step of forming the terminal areas is carried out in such a way that the terminal areas are formed at two or more separate positions and pseudo terminal areas corresponding to the terminal areas are also formed between the separate positions.

### CROSS REFERENCES TO RELATED APPLICATIONS

The present invention contains subject matter related Japanese Patent Application JP 2007-174688 filed in the Japan Patent Office on Jul. 3, 2007, the entire contents of which being incorporated herein by reference.

### BACKGROUND OF THE INVENTION

1. Field of the Invention

The present invention relates to a method for producing a display device and a display device, the display device having display elements such as organic light-emitting elements. More particularly, the present invention relates to a method for producing a display device and a display device, the display device being that of so-called complete solid sealed structure in which a driving panel having display elements is attached to a sealing panel with an adhesive layer interposed between them.

2. Description of the Related Art

It is recently expected that organic EL (electroluminescence) display devices having organic EL elements will replace liquid crystal display devices. Being selfluminous, organic EL display devices have a wide viewing angle and operate with a low electric power. In addition, they are quickly responsive to high-speed video signals for high-definition images. Efforts are being made to put them into practical use.

Unfortunately, organic EL elements have the disadvantage of being vulnerable to moisture. They easily absorb moisture upon contact with atmospheric air, decreasing in life and giving rise to dark spots (incapable of light emission) which deteriorate brightness. A possible way to exclude moisture in atmospheric air from organic EL elements is to completely cover the element substrate with a sealing substrate, with an adhesive layer interposed between them. The organic EL display device of such structure emits light through the sealing substrate. In other words, it is of top-emitting type in completely solid sealed structure.

The organic EL display device of the foregoing structure needs the terminal area to be protected with a protective member (such as a protective tape) so as to keep the terminal area away from the adhesive when the sealing substrate is bonded to the element substrate with the adhesive. According to a disclosure in Japanese Patent Laid-open No. 2004-247239, the organic EL display device of top emission type in complete solid sealed structure is produced by a method including a step of covering the terminal area with a protective member, a step of providing an adhesive layer between the element substrate and the sealing substrate in such a way that it covers the emitting elements and the protective member, and a step of removing part of the element substrate and the sealing substrate which have been bonded together with the adhesive layer interposed between them, such that the protective member is also removed together with that part of the substrates which is removed and the terminal area is exposed.

### SUMMARY OF THE INVENTION

Unfortunately, the step of removing the protective member and exposing the terminal area has the disadvantage of chipping the sealing substrate or the terminal area or being unable to remove the protective member completely.

Specifically, development of the organic EL display devices has recently progressed to cope with increase in screen size. When the large-sized organic EL display device is to be configured, the size of the element substrate is also increased but it is not necessary to arrange the terminal areas over the entire area of the element substrate. For example, the terminals have only to be arranged only at plural portions apart from each other which are positioned near opposite edges of the substrate. In such a case, depending on whether or not the terminal areas are arranged in place, the above-mentioned troubles with the removal of the protective member are liable to occur in an organic EL display device having a large screen.

The present invention was completed in view of the foregoing. It is desirable to provide a display device and a method for production thereof, the display device having two or more terminal areas arranged separately and the method being able to remove (peel off) adequately the protective member from the element substrate.

According to an embodiment of the present invention, the display device is produced by a method which includes a step of forming on an element substrate terminal areas for electrical connection of display elements with external circuits, a step of covering the terminal areas with a protective member, a step of sealing the element substrate with a sealing substrate placed thereon, with an adhesive layer interposed between them in such a way as to cover the display elements on the element substrate and also cover the protective member, and a step of removing part of the laminate body composed of the element substrate, the adhesive layer, and the sealing substrate and also removing the protective member, thereby exposing the terminal areas, wherein the step of forming the terminal areas is carried out in such a way that the terminal areas are formed at two or more separate positions and pseudo terminal areas corresponding to the terminal areas are also formed between the separate positions.

The foregoing method for producing the display device is characterized in that the pseudo terminal areas corresponding to the terminal areas are formed between the separate positions where the terminal areas are formed. The term “corresponding” means that the pseudo terminal areas are identical with the terminal areas in their shape. In other words, they have approximately the same film thickness. Therefore, even though terminal areas are arranged separately, the protective member uniformly covers the terminal areas and the pseudo terminal areas by the existence of the pseudo terminal areas. The result is that the protective member can be removed easily without troubles mentioned above.

The display device according to an embodiment of the present invention has the pseudo terminal areas between the terminal areas. This structure permits the protective member to cover them uniformly and to be removed easily without troubles. Therefore, the protective member can be removed (or peeled off from the element substrate) adequately even though the terminal areas are arranged at separate positions as in the case of organic EL display devices of top emission type in complete solid sealed type.

### BRIEF DESCRIPTION OF THE DRAWINGS

FIG. 1 is a schematic perspective view showing the structure of an organic EL display device to which an embodiment of the present invention is applied;

FIG. 2 is a sectional view showing the structure of an organic EL display device to which an embodiment of the present invention is applied;

FIGS. 3A to 3C are diagrams showing the relation between the amount of chipping of the sealing substrate and the position of the protective member; and

FIGS. 4A and 4B are diagrams showing the relation between the amount of chipping of the sealing substrate and the structure of the terminal areas on the element substrate.

### DETAILED DESCRIPTION OF THE PREFERRED EMBODIMENTS

The following description referring to the accompanying drawings is a detailed description of the display device and the method for production thereof according to the present invention.

The display device constructed as outlined below is exemplified by an organic EL display device of top emission type in complete solid sealed structure.

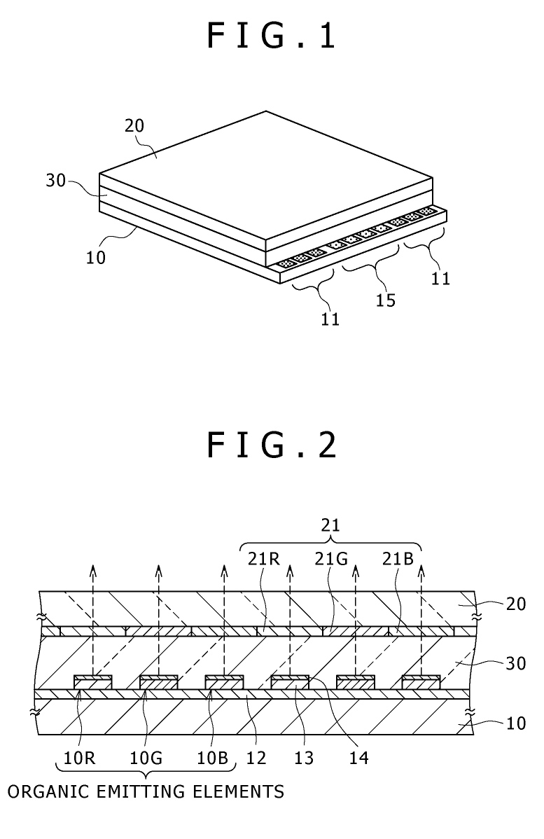

FIG. 1 is a schematic perspective view showing the structure of the organic EL display device. The illustrated organic EL display device is composed of an element substrate 10 and a sealing substrate 20, which face each other and adhere to each other over their entire surface by an adhesive layer 30 of thermosetting resin. The element substrate 10 has on its one side a terminal area 11 for external electrical connection through which the organic EL element (mentioned later) is supplied with signals and electric power. The terminal area 11 is formed from titanium (Ti) and aluminum (Al). It has an exposed surface which is not covered with the adhesive layer 30 and the sealing substrate 20. In addition, the terminal areas 11 are not arranged over the entire area of the electrode substrate 10 but, for example, arranged at the vicinity of both ends on one side of the electrode substrate in which the terminal areas 11 are in place. That is, the terminal areas 11 are divided into two parts and arranged at both ends of one side of the element substrate 10 with a certain distance apart. Between the separate parts of the terminal area 11 is arranged a pseudo terminal area 15 (mentioned later).

FIG. 2 is a sectional view showing the sectional structure of an organic EL display device. In the case of the illustrated organic EL display device, the element substrate 10 is made of an insulating material such as glass. On the element substrate 10 are arranged an organic EL element 10R (which emits red light), an organic EL element 10G (which emits green light), and an organic EL element 10B (which emits blue light). These organic EL elements regularly form a matrix pattern as a whole.

Each of the organic EL elements 10R, 10G, and 10B is composed of a first electrode 12 (as an anode), an organic layer 13 (containing a light-emitting layer), and a second electrode 14 (as a cathode), which are placed one over another upward from the element substrate 10.

The first electrode 12 functions also as a reflecting layer. It is formed from metal, such as platinum (Pt), gold (Au), chromium (Cr), and tungsten (W), or alloys thereof.

The organic layer 13 is formed in different manners depending on the light color emitted by the organic EL element. Each of the organic EL elements 10R and 10B is composed of a hole transporting layer, an emitting layer, and an electron transporting layer, which are placed one over another upward from the first electrode 12. The organic EL element 10G is composed of a hole transporting layer and an emitting layer, which are placed on top of the other upward from the first electrode 12. The hole transporting layer is intended for efficient hole injection into the emitting layer. The emitting layer emits light upon recombination of electrons and holes induced by an electric field applied to it. The electron transporting layer is intended for efficient electron injection into the emitting layer.

A typical material for the hole transporting layer of the organic EL element 10R is bis[(N-naphthyl)-N-phenyl]benzidine (α-NPD). A typical material for the emitting layer of the organic EL element 10R is 2,5-bis[4-[N-(4-methoxyphenyl)-N-phenylamino]]styrylbenzene-1,4-dicarbonitrile (BSB). A typical material for the electron transporting layer of the organic EL element 10R is 8-quinolinol aluminum complex (Alq₃).

A typical material for the hole transporting layer of the organic EL element 10B is α-NPD. A typical material for the emitting layer of the organic EL element 10B is 4,4-bis(2,2-diphenylvinyn)biphenyl (DPVBi). A typical material for the electron transporting layer of the organic EL element 10B is Alq₃.

A typical material for the hole transporting layer of the organic EL element 10G is α-NPD. A typical material for the emitting layer of the organic EL element 10G is a mixture of Alq₃ and coumarin 6 (C6: Coumarin6) (1 vol %).

The second electrode 14 is a translucent one, so that it emanates the light generated by the emitting layer. It is formed from a metal, such as silver (Ag), aluminum (Al), magnesium (Mg), calcium (Ca), and sodium (Na), or an alloy thereof.

The sealing substrate 20 is adjacent to the organic EL elements 10R, 10G, and 10B on the element substrate 10. It seals the organic EL elements 10R, 10G, and 10B in concert with the adhesive layer 30. It is formed from glass transparent to the light generated by the organic EL elements 10R, 10G, and 10B. It is provided with color filters 21 (21R, 21G, 21B). The color filters 21 pass the light generated by the organic EL elements 10R, 10G, and 10B. They also absorb extraneous light reflected by the organic EL elements 10R, 10G, and 10B and the wiring thereof, so as to improve contrast.

The organic EL display device constructed as mentioned above is produced by the following procedure. Although it is possible to produce more than one organic EL display device from one element substrate, the following example illustrates, for brevity, production of one organic EL display device from one element substrate.

Production of the organic EL display device starts with forming the organic emitting elements 10R, 10G, and 10B and the terminal area 11 for external electrical connection of these elements on the element substrate 10. The process of forming the organic emitting elements 10R, 10G, and 10B includes a first step of forming a plurality of the first electrodes 12 in parallel from the above-mentioned material, a second step of sequentially forming the hole injection layer, hole transporting layer, emitting layer, and electron transporting layer (which constitute the organic layer 13) from the above-mentioned materials on the first electrodes 12, and a third step of forming a plurality of the second electrodes 14 in parallel (perpendicular to the first electrodes 12). The terminal area 11 is formed from Ti—Al by PVD (physical vapor deposition).

Then, the terminal area 11 on the element substrate 20 is covered with a protective member (not shown), such as Kapton tape commercially available from Sumitomo 3M Limited, which is a heat-resistant masking tape. The protective member should have sufficient heat resistance because the adhesive layer 30 is subsequently cured by heating at a prescribed temperature for a prescribed period. Moreover, it should preferably have electrical conductivity. Such a conductive protective member prevents static electricity from adversely affecting thin film transistors (TFT) (not shown) attached individually to the organic emitting elements 10R, 10G, and 10B. The protective member should preferably have a thickness of 10 to 60 μm. The one thinner than 10 μm is not practicable, and the one thicker than 60 μm makes the adhesive layer 30 so thick as to narrow the viewing angle. The latter deteriorates the wide view angle characteristic of the organic EL display device.

After the terminal area 11 has been covered with a protective member, the element substrate 20 and the protective film are covered entirely with the adhesive layer 30. Then, the element substrate 10 is sealed with the sealing substrate 20, with the adhesive layer 30 interposed between them. In other words, the adhesive layer 30 is placed between the element substrate 10 and the sealing substrate 20 in such a way that it covers the organic emitting elements 10R, 10G, and 10B and the protective member, and the adhesive layer 30 joins together the element substrate 10 and the sealing substrate 20. Thus there is obtained a laminate body composed of the element substrate 10, the adhesive layer 30, and the sealing substrate 20. Before the laminate body is formed, the sealing substrate 10 is previously provided with the color filters 21.

The thus obtained laminate body, which is composed of the element substrate 10, the adhesive layer 30, and the sealing substrate 20, has its part (together with the protective member) removed so that the terminal area 11 is exposed. This step is intended to make the terminal area 11 expose itself, which is buried in the adhesive layer 30 between the element substrate 10 and the sealing substrate 20 when the laminate body is formed, by removing part of the laminate body and peeling the protective member from the terminal area 11. Partial removal of the laminate body is accomplished by scribing the sealing substrate 20 and the element substrate 10 of the laminate body placed on a glass scribing table. Scribing scratches a groove along which the substrate is broken.

This removal work is preferably done by using a special folding jig to apply a uniform force without damage to the substrate. The folding jig is used for manual removal work; however, it is also possible to be used for automated operation, of course.

The above-mentioned procedure completes the organic EL display device shown in FIGS. 1 and 2.

A critical step in the above-mentioned procedure is to remove the protective member and expose the terminal area 11. This step might chip off the sealing substrate 20 or the terminal area 11 or might leave the protective member unremoved. This holds true particularly in the case of large organic EL display devices exceeding 5 inches which have a large area of protective member. They present difficulties in removing the protective member completely.

Troubles involved in removing the protective member are due to the relation between the amount of chipping in the sealing substrate 20 which occurred in removing a part of the laminate body and the position of the protective member. Here, “chipping” denotes an oblique cut along the scribe line rather than a sharp cut perpendicular to the surface. “Amount of chipping” denotes how large chipping is.

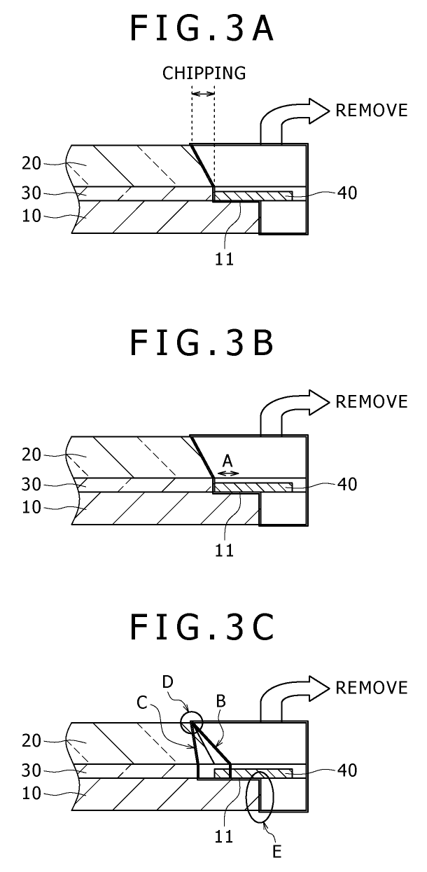

FIGS. 3A to 3C are schematic diagrams showing the relation between the amount of chipping of the sealing substrate and the position of the protective member.

If the sealing substrate 20 is chipped in the direction which coincides with the edge of the protective member 40, the protective member 40 can be removed most easily, as shown in FIG. 3A. Therefore, it is desirable to form the panel under this condition.

Also, if the amount of chipping of the sealing substrate 20 is uniform, the protective member 40 can be removed easily even though its edge position somewhat fluctuates as shown in FIG. 3B, in which “A” indicates fluctuation.

By contrast, if the amount of chipping of the sealing substrate 20 is not uniform, it is impossible to remove the protective member 40 consistently with a sufficient margin, as shown in FIG. 3C. Specifically, if the amount of chipping is large (as indicated by “B”), the protective member 40 partly remains under the sealing substrate 20. This situation makes it necessary to pull out or tear off the protective member 40 or results in the protective member 40 partly remaining unremoved. If the amount of chipping is small (as indicated by “C”), it is necessary to peel off the adhesive layer 30, and this results in the protective member 40 partly remaining unremoved. Moreover, if the amount of chipping is not uniform, the sealing substrate 20 suffers chipping (as indicated by “D”) or the terminal area suffers chipping (as indicated by “E”).

As mentioned above, in the case where the amount of chipping is not uniform in the sealing substrate 20, the protective member 40 cannot be removed consistently, which easily rises the problems in removing. This situation can be avoided if a stable relationship is established between the amount of chipping of the sealing substrate 20 and the position of the protective member 40.

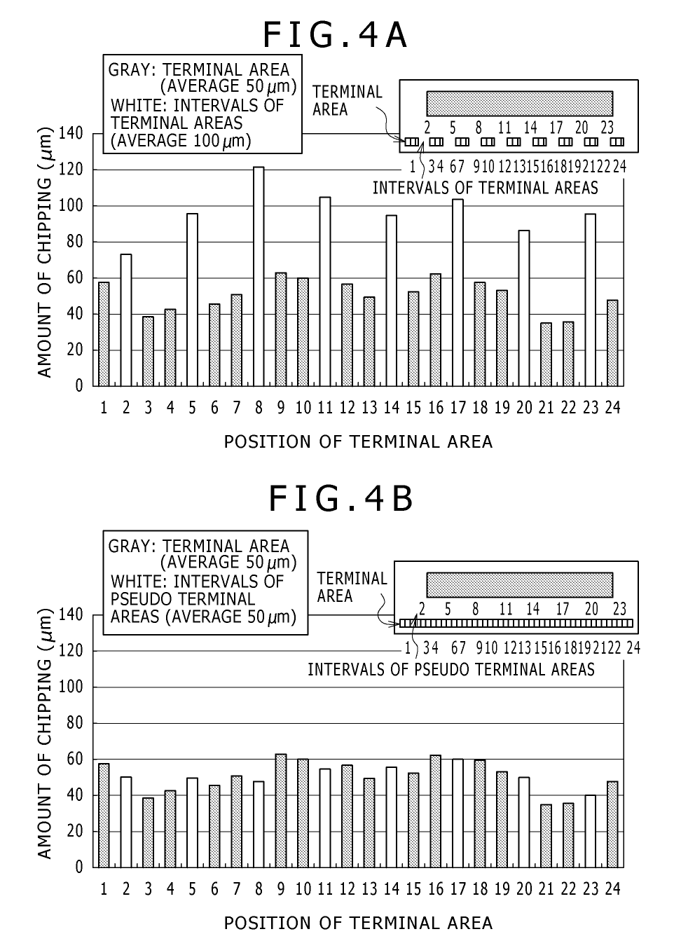

It is found that the amount of chipping of the sealing substrate 20 depends on the structure of the terminal area of the element substrate 10. FIGS. 4A and 4B show the relation between the amount of chipping of the sealing substrate and the structure of the terminal area of the element substrate.

FIG. 4A represents the case in which every terminals are arranged a certain distance apart. In this case, the amount of chipping differs from one place (where there exist terminal areas 11) to another (where there exist no terminal areas 11). The amount of chipping is larger in the latte place than the former place.

By contrast, FIG. 4B represents the case in which a pseudo (or dummy) terminal is interposed between every two terminal areas 11. In this case the amount of chipping fluctuates only a little and remains nearly uniform over the entire range.

As shown above, the amount of chipping of the sealing substrate 20 depends on the structure (or arrangement) of the terminal area 11 of the element substrate 10. To make the amount of chipping uniform, it is necessary to place the pseudo (or dummy) terminal in empty space on which the terminal areas 11 are not placed, that is, in the space between the terminal areas 11 are placed apart.

For the reason mentioned above, the organic EL display device according to the embodiment has the pseudo terminal area 15 corresponding to the terminal area 11 between every terminal areas 11. Here, “corresponding to the terminal areas 11” means the pseudo terminal area 15 has the same feature in shape with the terminal area 11. Specifically, the pseudo terminal area 15 has approximately the same thickness as the terminal area 11. Therefore, it functions in the same way as the terminal area 11 as far as the amount of chipping of the sealing substrate 20 is concerned.

The pseudo terminal area 15 can be formed at the same time as the terminal area 11 is formed by using a mask pattern for both.

It is to be noted that, forming the pseudo terminal area 15 in every space between adjacent sets of the terminal areas 11 is desirable but not essential; however, at least one pseudo terminal area 15 should be formed. The pseudo terminal area 15 is not specifically restricted in shape; it may either be in the same pattern or differ in pattern from the terminal area 11.

The foregoing embodiment demonstrated an organic EL display device and a method for production thereof. The organic EL display device has the pseudo terminal area 15 between the terminal areas 11 placed apart so that the protective member 40 uniformly covers the terminal areas 11 and the pseudo terminal areas 15. This structure makes the amount of chipping of the sealing substrate 20 uniform by making the relationship between the amount of chipping of the sealing substrate 20 and the terminal structure on the element substrate 10 uniform. The advantage of the organic EL display device having the pseudo terminal area 15 as mentioned above is that the step of removing the protective member 40 to expose the terminal area 11 can be accomplished without the sealing substrate 20 and the terminal area 11 being chipped off or the protective member 40 partly remaining unremoved.

The foregoing advantage is favorable particularly to large-sized organic EL display devices. Even in the case of an organic EL display device of top emission type in complete solid sealed structure with a screen larger than 5 inches which usually has more than one terminal area 11 arranged separately, the protective member 40 works uniformly, thereby reducing the problems which occur in removal of the protective member 40. Thus, the protective member 40 can be peeled off smoothly from the element substrate 10. This contributes to high reliability and yield of the organic EL display device.

The present invention has been described above with reference to its preferred embodiment; however, the embodiment is not intended to restrict the scope thereof but can be changed and modified within the scope thereof.

Although the foregoing embodiment is applicable to an organic EL display device of top emission type in complete solid sealed structure, it may also be applicable to any other type of organic EL display device as well as liquid crystal display device etc.

What is claimed is:

1. A method for producing a display device, comprises the steps of:
forming on an element substrate terminal areas for electrical connection of display elements with external circuits;
covering said terminal areas with a protective member;
sealing said element substrate with a sealing substrate placed thereon, with an adhesive layer interposed between them in such a way as to cover said display elements on said element substrate and also cover said protective member; and
removing part of the laminate body composed of said element substrate, said adhesive layer, and said sealing substrate and also removing said protective member, thereby exposing said terminal areas,
wherein said step of forming said terminal areas is carried out in such a way that said terminal areas are formed at two or more separate positions and pseudo terminal areas corresponding to said terminal areas are also formed between said separate positions.

2. A display device, produced by the steps of:
forming on an element substrate terminal areas for electrical connection of display elements with external circuits;
covering said terminal areas with a protective member;
sealing said element substrate with a sealing substrate placed thereon, with an adhesive layer interposed between them in such a way as to cover said display elements on said element substrate and also cover said protective member; and
removing part of the laminate body composed of said element substrate, said adhesive layer, and said sealing substrate and also removing said protective member, thereby exposing said terminal areas,
wherein said terminal areas are formed at two or more separate positions, and
pseudo terminal areas corresponding to said terminal areas are also formed between said separate positions.
